(19) United States
(12) Patent Application Publication
(10) Pub. No.: US 2007/0281390 A1
(43) Pub. Date: Dec. 6, 2007

(54) Manufacturing method of a package substrate

(75) Inventors: Myung-Sam Kang, Seo-gu (KR); Je-Gwang Yoo, Yongin-si (KR); Jung-Hyun Park, Cheongju-si (KR); Ji-Eun Kim, Gwangmyeong-si (KR); Hoe-Ku Jung, Daedeok-gu (KR); Jin-Yong An, Seo-gu (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/727,852

(22) Filed: Mar. 28, 2007

(30) Foreign Application Priority Data
Jun. 2, 2006 (KR) 10-2006-0049999

(51) Int. Cl. H01L 21/00

(52) U.S. Cl. 438/106

(57) ABSTRACT

The present invention relates to a manufacturing method of a package substrate. A manufacturing method of a package substrate for mounting an electric component by connecting electrodes of the electric component to bonding pads, includes: manufacturing a buried pattern substrate having a circuit pattern and bonding pads buried in an insulating layer and having a seed layer laminated on the insulating layer, laminating a dry film onto the seed layer and removing the seed layer and the dry film of the upper side of the bonding pads, performing surface-treatment using the remaining seed layer as a plating lead; and removing the remaining seed layer and the dry film such that the circuit pattern is exposed.

### CROSS-REFERENCE TO RELATED APPLICATIONS

This application claims the benefit of Korean Patent Application No. 2006-0049999 filed with the Korean Intellectual Property Office on Jun. 2, 2006, the disclosure of which is incorporated herein by reference in its entirety.

### BACKGROUND

1. Technical Field

The present invention relates to a manufacturing method of a package substrate.

2. Description of the Related Art

Recently, although the size of an IC is decreasing, the number of leads is increasing. To solve this problem, the use of the package substrate, such as a BGA (Ball grid array) and CSP (chip scale package) has recently been made popular. In the package substrate, the substrate can be made to have higher density, facilitated by the use of solder balls. Thus, the package substrate may actively be applied for mounting semiconductor chips.

In the package substrate, gold plating is applied in many cases to ball pads or bonding fingers, etc. (known as ‘bonding pads’), connected with the semiconductor chip for improving electrical connection, and plating lead lines are formed on the substrate for this plating.

FIG. 1 is a fabrication diagram of a printed circuit board using a plating lead line according to prior art. In FIG. 1, a manufacturing method of the printed circuit board is illustrated, and the manufacturing method is as follows.

A copper-clad laminate is prepared for making a printed circuit board (process 1). Afterwards, a hole is formed in order to connect the top and bottom of the prepared the copper-clad laminate (process 2). Generally, a drill can be used for the hole forming. This hole is then plated (process 3). The top and bottom of the copper foil are electrically connected. In process 4, a dry film is laminated, with exposure, development, and etching performed to form a circuit pattern. This is a method of forming the circuit pattern using the subtractive method. Afterwards, a seed layer is formed on the printed circuit board through electroless plating (process 5). Parts of the seed layer will become plating lead lines. In process 6, only the parts which will not become plating lead lines are developed. A circuit pattern is formed after removing the seed layer attached over the entire surface of the printed circuit board and weak etching (process 7, 8).

Next, parts that are to be gold-plated are developed (process 9). These parts are plated with nickel and gold using the already formed plating lead lines (process 10). After the dry film is peeled off (process 11), the thin plating lead lines are removed through weak etching (process 12). After a solder-resist is coated (process 13), and only the gold-plated parts are developed, the product manufacturing is completed (process 13, 14).

Forming the plating lead lines by prior art, however, poses limits on the density of the circuit. Also, an additional process is required of removing the plating lead lines after the plating, and the signal noise is generated by plating lead line remains.

### SUMMARY

An aspect of this invention is to provide a manufacturing method of a package substrate which does not use plating lead lines.

Additional aspects and advantages of the present invention will become apparent and more readily appreciated from the following description, including the appended drawings and claims, or may be learned by practice of the invention.

A manufacturing method of a package substrate for mounting an electric component by connecting electrodes of the electric component to bonding pads, which includes: manufacturing a buried pattern substrate having a circuit pattern and bonding pads buried in an insulating layer and having a seed layer laminated on the insulating layer, laminating a dry film onto the seed layer and removing the seed layer and the dry film of the upper side of the bonding pads, performing surface-treatment using the remaining seed layer as a plating lead; and removing the remaining seed layer and the dry film such that the circuit pattern is exposed.

The manufacturing of the buried pattern substrate may include: laminating the seed layer onto a carrier board, forming the circuit pattern and the bonding pads on the seed layer, laminating the carrier board onto an insulating layer such that the circuit pattern and the bonding pads of the carrier board are buried in the insulating layer, and removing the carrier board.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a fabrication diagram of a printed circuit board using plating lead lines according to prior art.

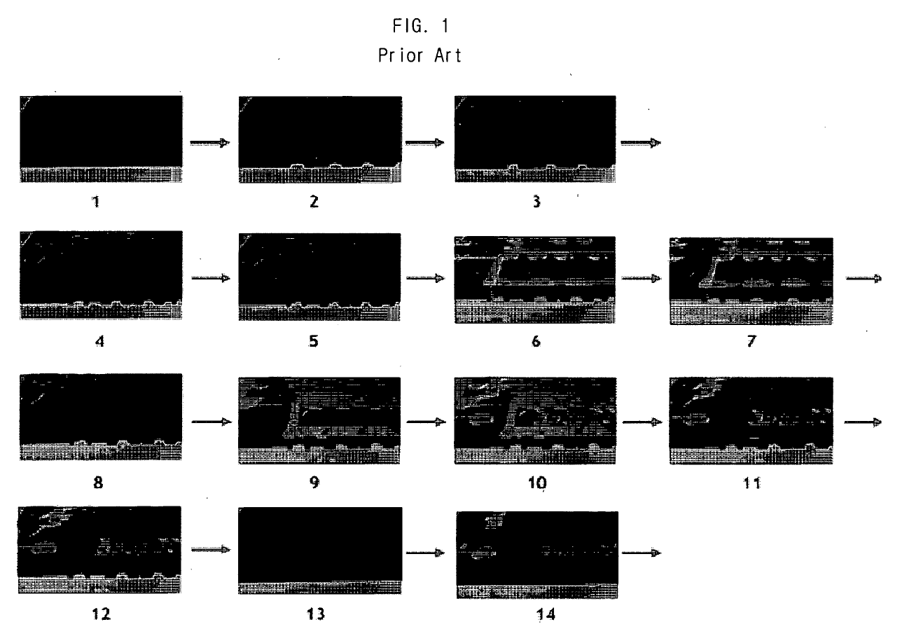

FIG. 2 is a production flow chart of a package substrate according to an embodiment of the invention.

FIG. 3 is a fabrication diagram of a package substrate according to an embodiment of the invention.

### DETAILED DESCRIPTION

Embodiments of the manufacturing method of package substrate according to the invention will be described below in more detail with reference to the accompanying drawings. In the description with reference to the accompanying drawings, those components are rendered the same reference number that are the same or are in correspondence, regardless of the figure number, and redundant explanations are omitted.

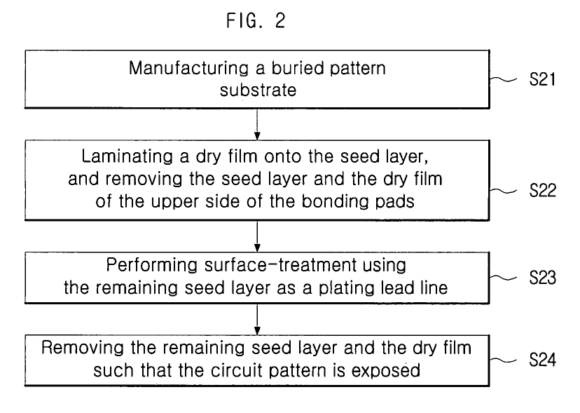

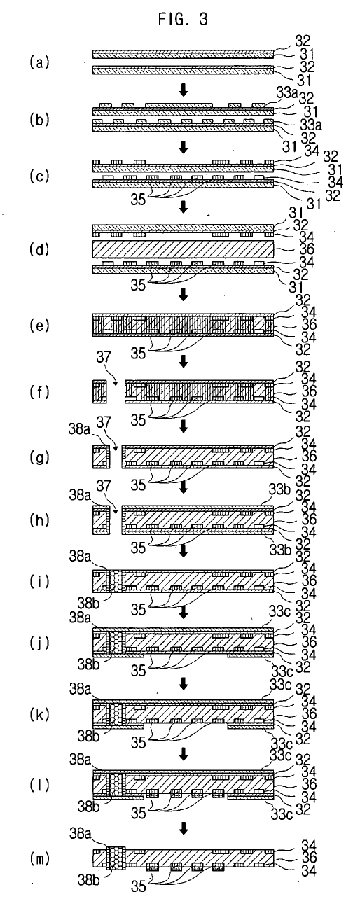

FIG. 2 is a flowchart showing a manufacturing method of a package substrate according to an embodiment of the present invention. FIG. 3 is a fabrication diagram of a package substrate. Referring to FIG. 3, carrier boards 31, seed layers 32, dry films 33a, 33b, 33c, circuit patterns 34, bonding pads 35, an insulating layer 36, a via hole 37, an electroless plating layer 38a, and a fill plating layer 38b are illustrated.

S21 of FIG. 2 is the operation of making a buried pattern substrate, in which the bonding pads 35 and the circuit patterns 34 are buried in the insulating layer 36, and the seed layer 32 is laminated on the insulating layer 36. S21 corresponds to (a) to (e) of FIG. 3. Process (a) of FIG. 3 is the operation of laminating the seed layer 32 onto the carrier board 31. The carrier board 31 plays the role of supporting the seed layer 32, and will subsequently be removed by another process. Generally, the carrier board 31 is made of metal. The seed layer 32, which is temporarily needed to form the circuit pattern 34 and bonding pad 35, is also formed by electroless plating. This embodiment uses two carrier boards for forming two circuit patterns 34 on the surface of the insulating layer 36.

Process (b) of FIG. 3 is the operation of laminating the dry film 33a onto the seed layer 32 for a semi-additive operation and removing the dry film 33a which will become the circuit pattern 34 and the bonding pads 35. The dry film 33a is photosensitive, and is thus hardened by light. Therefore, after the dry film 33a is laminated onto the seed layer 32, it is exposed excluding the parts that will become the circuit pattern 34 and bonding pads 35. After the dry film 33a is developed, parts of the seed layer 32 which will become circuit pattern 34 and bonding pads 35 is exposed as in (b) of FIG. 3.

Process (c) of FIG. 3 is the operation of forming the circuit pattern 34 and the bonding pads 35. The upper side of the seed layer 32 is plated in (b) of FIG. 3. When the rest of the dry film 33a is removed, the configuration shown in (c) of FIG. 3 is obtained.

Process (d) of FIG. 3 is the operation of arranging the carrier boards 31, on which the circuit patterns 34 and bonding pads 35 are formed, symmetrically about the insulating layer 36. At this time, the circuit patterns 34 and bonding pads 35 face toward the insulating layer 36 such that the circuit pattern 34 and bonding pads 35 are buried. Prepreg may be used for the insulating layer 36.

Process (e) of FIG. 3 is the operation of removing the carrier boards 31 after the carrier boards 31 are collectively laminated on the insulating layer 36. When the carrier boards 31 are removed, the seed layers 32 are exposed as in (e) of FIG. 3. Moreover, the circuit patterns 34 and bonding pads 35 stacked on the seed layers 32 are buried in the insulating layer 36 as in (e) of FIG. 3.

The operations (f) to (i) of FIG. 3, are for forming a via hole 37 for electrically connecting the upper and lower layers of circuit pattern 34. First, a via hole 37 is punched by a drill or laser. Afterwards, an electro-less plating layer 38a is formed in the via hole 37 as in (g) of FIG. 3. In order to plate the inside of the via hole 37, dry films 33b are applied on parts excluding the via hole 37 as in (h) of FIG. 3. Then, the via hole 37 is filled by a fill plating layer 38b through electroplating. Process (i) of FIG. 3 shows the form after filling the fill plating layer 38b in the via hole 37 and removing the dry films 33b.

The operations (j) to (m) of FIG. 3 are for performing surface-treatment on the bonding pads 35. The dry films 33c are laminated as in (j) of FIG. 3. The dry film 33c is opened at a portion at which the bonding pads 35 are to be formed, through exposure and development processes. The seed layer 32 on the upper side of the bonding pads 35 is exposed as a result of this opening. Process (k) of FIG. 3 is the process for removing the seed layer 32 in the opened part. The seed layer 32 is removed through flash etching. Flash etching is an etching process that is milder than regular etching. As the seed layer 32 is removed, the bonding pads 35 are exposed. Processes (j) and (k) of FIG. 3 correspond to S22 of FIG. 2. Process (l) of FIG. 3 is of plating the bonding pads 35 in correspondence to S23 of FIG. 3. At this time, the seed layer 32 which has not been removed serves as plating lead lines. As (l) of FIG. 3 is the cross-sectional view, it may look as if the bonding pads 35 and the seed layer 32 are electrically disconnected, but actually, the bonding pads 35 and the seed layer 32 are electrically connected, so that an electric current flows through the bonding pads 35 when the electric current is supplied from the outside. In this embodiment, the bonding pads 35 are plated with gold.

Process (m) of FIG. 3 is the operation of exposing the circuit patterns 34 by removing the rest of the dry films 33c and the seed layers 32. Afterwards, the process of coating the surface of the PCB with a solder-resist and opening the bonding pads is additionally performed.

As described, according to embodiments of the present invention, the degree of freedom in circuit design is improved, since additional plating lead lines for the gold coating are unnecessary. There are benefits also in creating high density circuit products, because additional circuit design is possible in the parts in which the plating lead lines would have been formed. Furthermore, the electrical characteristics of the package substrate can be improved by preventing signal noise caused by plating lead line remains.

Moreover, the effectiveness of the process is increased, because the process of forming plating lead lines is unnecessary.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A manufacturing method of a package substrate for mounting an electric component by connecting electrodes of the electric component to bonding pads, the method comprising:
manufacturing a buried pattern substrate having a circuit pattern and bonding pads buried in an insulating layer and having a seed layer laminated on the insulating layer;
laminating a dry film onto the seed layer, and removing the seed layer and the dry film of the upper side of the bonding pads;
performing surface-treatment using the remaining seed layer as a plating lead line; and
removing the remaining seed layer and the dry film such that the circuit pattern is exposed.

2. The method of claim 1, wherein the manufacturing comprises:
laminating the seed layer onto a carrier board;
forming the circuit pattern and the bonding pads on the seed layer;
laminating the carrier board onto an insulating layer such that the circuit pattern and the bonding pads of the carrier board are buried in the insulating layer; and
removing the carrier board.
